(19) United States
(12) Patent Application Publication
(10) Pub. No.: US 2023/0207756 A1
(43) Pub. Date: Jun. 29, 2023

(54) METHOD FOR PRODUCING LIGHT-EMITTING UNIT AND LIGHT-EMITTING UNIT

(71) Applicant: NICHIA CORPORATION, Anan-shi (JP)

(72) Inventor: Motokazu YAMADA, Tokushima-shi (JP)

(73) Assignee: NICHIA CORPORATION, Anan-shi (JP)

(21) Appl. No.: 18/067,014

(22) Filed: Dec. 16, 2022

(30) Foreign Application Priority Data
Dec. 27, 2021 (JP) 2021-212024

(51) Int. Cl. H01L 33/60; H01L 25/075; H01L 33/62; H01L 23/00

(52) U.S. Cl. CPC H01L 33/60; H01L 24/13; H01L 24/81; H01L 25/0753; H01L 33/62; H01L 24/16; H01L 2224/1319; H01L 2224/8192; H01L 2224/16225; H01L 2224/81201; H01L 2224/81911; H01L 2933/0058; H01L 2933/0066

(57) ABSTRACT

A method for producing a light-emitting unit includes providing a solder composition on a wiring layer of a substrate. The solder composition contains a solder, a flux, and light-reflective particles. The method further includes placing a light-emitting element having an electrode on the solder composition such that the electrode of the light-emitting element faces the solder composition, and melting the solder by a reflow process to allow the light-reflective particles to move to a surface of the solder composition, and to electrically couple the electrode with the wiring layer via the solder.

### CROSS REFERENCE TO RELATED APPLICATION

This application claims priority to Japanese Patent Application No. 2021-212024, filed on Dec. 27, 2021, the disclosure of which is hereby incorporated by reference in its entirety.

### BACKGROUND

The present disclosure relates to a method for producing a light-emitting unit and a light-emitting unit.

Light-emitting units including, in part, semiconductor light-emitting elements, represented by light-emitting diodes (LEDs), have been widely used. Japanese Patent Publication No. 2020-077870 discloses a LED unit in which a light-emitting element is mounted to a printed board using an anisotropic bonding film composed of a solid resin, solder particles and a flux.

### SUMMARY

In the field of light-emitting units including light-emitting elements on a substrate, there is a demand for further improvement in light extraction efficiency.

According to an embodiment of the present disclosure, a method for producing a light-emitting unit includes: (A) providing a solder composition on a wiring layer of a substrate, the solder composition containing a solder, a flux, and light-reflective particles; (B) placing a light-emitting element having an electrode on the solder composition such that the electrode of the light-emitting element faces the solder composition; and (C) melting the solder by a reflow process to allow the light-reflective particles to move to a surface of the solder composition, and to electrically couple the electrode with the wiring layer via the solder.

According to another embodiment of the present disclosure, a light-emitting unit includes: a light-emitting element having an upper surface and a lower surface that is opposite to the upper surface, the light-emitting element including a pair of electrodes provided at the lower surface; a substrate having a wiring layer; a bonding member located between the wiring layer of the substrate and each of the electrodes, the bonding member including a solder to electrically couple the electrode with the wiring layer; and a light reflecting layer located at a part of a surface of the bonding member that is in contact with neither the electrodes nor the wiring layer, wherein the light reflecting layer includes light-reflective particles and a flux.

According to an embodiment of the present disclosure, the light extraction efficiency of a light-emitting unit can be improved.

### BRIEF DESCRIPTION OF THE DRAWINGS

FIG. 1A is a diagram schematically showing an example of the external appearance of a light-emitting unit as viewed from above according to an embodiment of the present disclosure, and FIG. 1B is a schematic cross section of the light-emitting unit of FIG. 1A taken along line IB--IB in FIG. 1A.

FIG. 2 is an enlarged schematic cross-sectional view showing a part of the cross section shown in FIG. 1B, which includes a light-emitting element and its surroundings.

FIG. 3 is a schematic cross-sectional view showing another example of the distribution of light-reflective particles.

FIG. 4 is a schematic cross-sectional view showing still another example of the distribution of light-reflective particles.

FIG. 5 is a schematic cross-sectional view showing still another example of the distribution of light-reflective particles.

FIG. 6 is a schematic cross-sectional view showing still another example of the distribution of light-reflective particles.

FIG. 7 is a schematic cross-sectional view of a light-emitting unit according to another embodiment of the present disclosure.

FIG. 8 is an enlarged schematic cross-sectional view showing a part of FIG. 7.

FIG. 9 is a schematic cross-sectional view of a light-emitting unit according to still another embodiment of the present disclosure.

FIG. 10 is an enlarged schematic cross-sectional view showing one of the light sources shown in FIG. 9 and its surroundings.

FIG. 11 is a schematic top view of a partition member taken out from the light-emitting unit shown in FIG. 9.

FIG. 12 is a flowchart for illustrating an exemplary method for producing a light-emitting unit according to still another embodiment of the present disclosure.

FIG. 13 is a schematic cross-sectional view for illustrating an exemplary method for producing a light-emitting unit according to still another embodiment of the present disclosure.

FIG. 14 is a schematic cross-sectional view for illustrating an exemplary method for producing a light-emitting unit according to still another embodiment of the present disclosure.

FIG. 15 is a schematic cross-sectional view for illustrating an exemplary method for producing a light-emitting unit according to still another embodiment of the present disclosure.

FIG. 16 is a schematic cross-sectional view for illustrating the first variation example of the light-emitting unit production method.

FIG. 17 is a schematic cross-sectional view for illustrating the first variation example of the light-emitting unit production method.

FIG. 18 is a schematic cross-sectional view for illustrating the second variation example of the light-emitting unit production method.

FIG. 19 is a schematic cross-sectional view for illustrating a configuration example where an underfill material is provided between the lower surface of a light-emitting element and the upper surface of the substrate.

### DETAILED DESCRIPTION

Embodiments of the present disclosure will now be described in detail with reference to the drawings. The following embodiments are illustrative, and the light-emitting unit and the production method thereof according to the present disclosure are not limited thereto. For example, the numerical values, shapes, materials, steps, and the order of steps, etc., to be shown in the following embodiments are merely examples, and various modifications can be made thereto so long as they do not lead to technical contradictions. The embodiments described below are merely illustrative, and various combinations are possible so long as they do not lead to technical contradictions.

The size, the shape, etc., of the components shown in the figures may be exaggerated for the ease of understanding, and they may not represent the size and the shape of the components, the size relationship therebetween in an actual light-emitting unit. Some components may be omitted in order to prevent the figures from becoming excessively complicated.

In the following description, components of like functions may be denoted by like reference signs and may not be described redundantly. Terms indicating specific directions and positions (e.g., “upper”, “lower”, “right”, “left”, and other terms including such terms) may be used in the following description. Note however that these terms are used merely for the ease of understanding relative directions or positions in the figure being referred to. The arrangement of components in figures from documents other than the present disclosure, actual products, actual manufacturing apparatuses, etc., does not need to be equal to that shown in the figure being referred to, as long as it conforms with the directional or positional relationship as indicated by terms such as “upper” and “lower” in the figure being referred to. In the present disclosure, the term “parallel” encompasses cases where two straight lines, sides, planes, etc., are in the range of about 0±5°, unless otherwise specified. In the present disclosure, the term “perpendicular” or “orthogonal” encompasses cases where two straight lines, sides, planes, etc., are in the range of about 90±5°, unless otherwise specified.

### Embodiment of Light-Emitting Unit

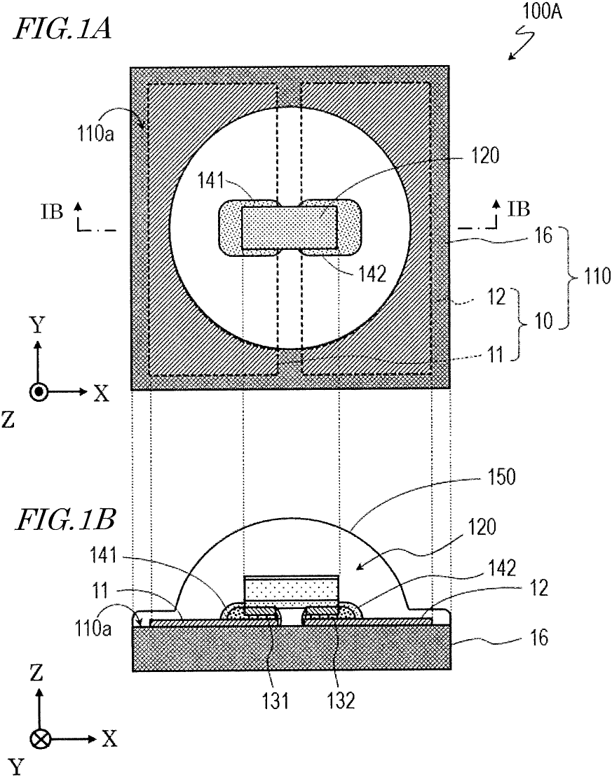

FIGS. 1A and 1B shows an example of the external appearance of a light-emitting unit according to an embodiment of the present disclosure. In FIG. 1A, the external appearance of the light-emitting unit as viewed from above and, in FIG. 1B, a schematic vertical cross section of the light-emitting unit, taken in the vicinity of a central part of the light-emitting unit along line IB--IB, are shown. In FIGS. 1A and 1B, arrows that are indicative of X direction, Y direction and Z direction, which are perpendicular to one another, are also shown for the sake of convenience in description. Arrows that are indicative of these directions may also be shown in other drawings of the present disclosure.

The light-emitting unit 100A shown in FIGS. 1A and 1B is an example of a light-emitting unit in which a light-emitting element is flip-chip bonded to a wiring layer of a substrate. The light-emitting unit 100A includes a substrate 110, a light-emitting element 120 that has a pair of electrodes, bonding members 131, 132, a light reflecting layer 141 that covers a part of the bonding member 131, and a light reflecting layer 142 that covers a part of the bonding member 132. In the configuration illustrated in FIGS. 1A and 1B, the light-emitting unit 100A further includes an encapsulation member 150, which covers the structure on the upper surface 110a of the substrate 110, such as the light-emitting element 120.

The substrate 110 includes a wiring layer 10 and a base 16 that supports the wiring layer 10. The wiring layer 10 includes a first wiring 11 and a second wiring 12. Herein, the upper surface 110a of the substrate 110 has the shape of a rectangle, and one side of the rectangle is parallel to the X or Y direction.

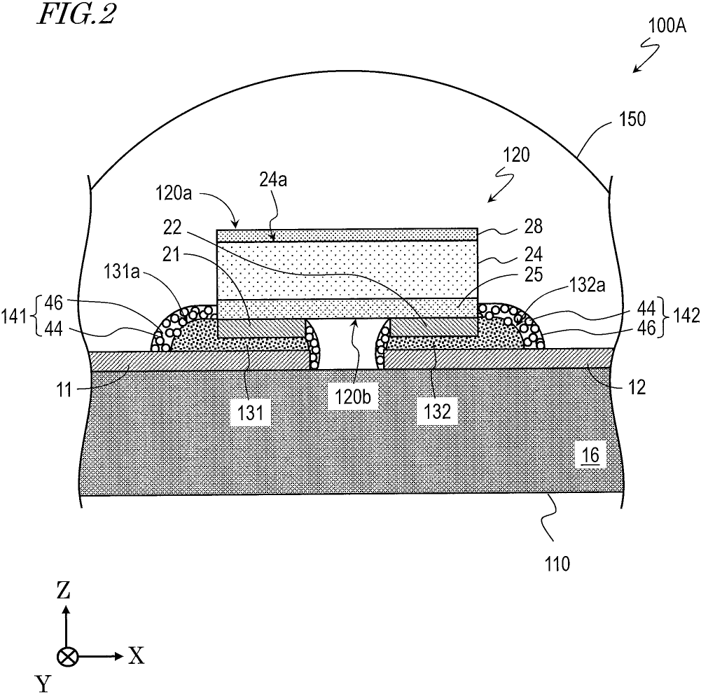

FIG. 2 is an enlarged view schematically showing a part of the cross section shown in FIG. 1B, which includes the light-emitting element 120 and its surroundings. The light-emitting element 120 has a lower surface 120b facing toward the substrate 110 and an upper surface 120a located on a side opposite to the lower surface 120b. The light-emitting element 120 has an electrode (first electrode) 21 and an electrode (second electrode) 22 on the lower surface 120b side.

In the configuration illustrated in FIG. 2, the light-emitting element 120 includes a light-transmitting substrate 24, a semiconductor multilayer structure 25, and a reflective film 28. The reflective film 28 may be provided on the upper surface 24a of the light-transmitting substrate 24. In this example, the upper surface of the reflective film 28 forms the upper surface 120a of the light-emitting element 120. The semiconductor multilayer structure 25 is located on a principal surface of the light-transmitting substrate 24 which is opposite to the upper surface 24a. The aforementioned electrodes 21 and 22 are provided on a surface of the semiconductor multilayer structure 25 which is opposite to the interface with the light-transmitting substrate 24. The electrodes 21 and 22 have the function of bringing an electric current into the semiconductor multilayer structure 25.

Each of the bonding members 131 and 132 electrically couples the light-emitting element 120 with the wiring layer 10 of the substrate 110. As for the bonding members 131 and 132, at least a part of the bonding member 131 is located between the electrode 21 of the light-emitting element 120 and the first wiring 11 of the wiring layer 10. Meanwhile, at least a part of the bonding member 132 is located between the electrode 22 of the light-emitting element 120 and the second wiring 12 of the wiring layer 10.

As schematically shown in FIG. 2, the light-emitting unit 100A includes the light reflecting layer 141 that covers a part of the surface 131a of the bonding member 131. The light reflecting layer 141 is located at a part of the surface 131a of the bonding member 131 that is in contact with neither the electrode 21 of the light-emitting element 120 nor the wiring layer 10 of the substrate 110. The light-emitting unit 100A also includes the light reflecting layer 142 that covers a part of the surface 132a of the bonding member 132. The light reflecting layer 142 is located at a part of the surface 132a that is in contact with neither the electrode 22 nor the wiring layer 10, in a similar manner to the light reflecting layer 141.

The light reflecting layers 141, 142 and the bonding members 131, 132 are realized by solidifying a solder composition 30, which will be described later. As will be described later in detail, the solder composition 30 contains solder particles, a flux, light-reflective particles, and a solvent. The bonding members 131, 132 are mainly made of the solder, and the light reflecting layers 141, 142 include the flux and light-reflective particles originally contained in the solder composition 30. The solder composition 30 may, or may not, contain a resin such as flux. Note that, however, the solder composition 30 does not contain a thermosetting resin (particularly, epoxy resin), which is likely to be discolored when irradiated with blue light.

As schematically shown in FIG. 2, each of the light reflecting layer 141 and the light reflecting layer 142 includes a flux 46 and light-reflective particles 44, all or some of which are present in the flux 46. Examples of the light-reflective particles 44 include titanium oxide particles, aluminum oxide particles, silicon dioxide particles, and zirconium dioxide particles. The light reflecting layer 141 and the light reflecting layer 142 typically take on a white color. In this specification, the term “light-reflective” refers to exhibiting a reflectance of 70% or higher over the entire visible wavelength range from 430 nm to 700 nm inclusive. On the other hand, the reflectance of tin, which is a primary component of usual solder compositions, over the visible range is about 50% at most. Further, usual solder compositions lose their gloss at the surface due to oxidation over time, so that the reflectance can decrease.

According to an embodiment of the present disclosure, a greater part of light emitted from the light-emitting element 120 and traveling toward the bonding members 131, 132 can be reflected by the light reflecting layers 141, 142 provided over the surfaces of the bonding members 131, 132. That is, the absorption of the light by the solder is small as compared with mounting with the use of a usual solder and, as a result, a greater part of the light can be extracted from the light-emitting unit, so that the light extraction efficiency can be improved.

The light reflecting layer 141 can cover 20% to 100%, inclusive, of a portion of the surface 131a of the bonding member 131 which is not in contact with any of the electrode 21 and the first wiring 11. From the viewpoint of suppressing light absorption at the solder surface, it is more advantageous that the light reflecting layer 141 covers 50% or more of the above-described portion of the surface 131a of the bonding member 131. Also, the light reflecting layer 142 preferably covers 20% to 100%, inclusive, of a portion of the surface 132a of the bonding member 132 which is not in contact with any of the electrode 22 and the second wiring 12. More preferably, the light reflecting layer 142 covers 50% or more of that portion. When greater part of the portions of the surfaces of the bonding members 131, 132 which are not in contact with any of the electrodes of the light-emitting element 120 and the wiring layer 10 is covered with the light reflecting layers 141, 142, the extraction efficiency of the light can be further improved.

It is beneficial that the difference in refractive index (e.g., the difference in refractive index for light at the wavelength of 450 nm) between the material of the light-reflective particles 44 and the material of the flux 46 is 0.5 or greater. This is because total reflection is likely to occur at the interface between the light-reflective particles 44 and the flux 46 and, as a result, the light extraction efficiency improves. From the viewpoint of improving the light extraction efficiency, it is advantageous that the average particle size of the light-reflective particles 44 is in the range of equal to or greater than 0.1 µm and equal to or smaller than 10 µm. Here, the “average particle size” refers to a particle size at which the cumulative value reaches 50% in a cumulative distribution on a volume basis (D₅₀: median particle size). The central particle size can be measured by a laser diffraction particle size distribution measuring device (e.g., MASTER SIZER 2000 manufactured by MALVERN).

The thickness of the light reflecting layer 141 along the normal direction of the surface 131a of the bonding member 131 is in the range of, for example, equal to or greater than 0.1 µm and equal to or smaller than 30 µm. The thickness of the light reflecting layer 142 along the normal direction of the surface 132a of the bonding member 132 is also in the range of, for example, equal to or greater than 0.1 µm and equal to or smaller than 30 µm.

In the examples shown in FIGS. 1A and 1B and FIG. 2, the light-emitting unit 100A further includes an encapsulation member 150 that covers the structure on the substrate 110. The encapsulation member 150 is a light-transmitting member and covers at least the light reflecting layers 141, 142 and the light-emitting element 120 as shown in FIG. 2. Herein, in this specification, the term “light-transmitting” is to be interpreted to encompass exhibiting a diffusive property for incoming light and is not limited to being “transparent”. For example, the encapsulation member 150 may include a light diffusing material dispersed therein, which has a different refractive index from that of the base material of the encapsulation member 150, so that the encapsulation member 150 can have a light diffusing function.

As will be described later, the flux 46 in the light reflecting layers 141, 142 can be decomposed when irradiated with the light from the light-emitting element 120. Since the encapsulation member 150 is provided on the substrate 110 so as to cover the light reflecting layers 141, 142, falling off of the light-reflective particles 44 from the bonding members 131, 132 can be suppressed even if the flux 46 is partially or entirely lost by photodecomposition. Since falling off of the light-reflective particles 44 is suppressed, decrease in reflectance of the light reflecting layers 141, 142, which is attributed to the falling off of the light-reflective particles 44, can be avoided.

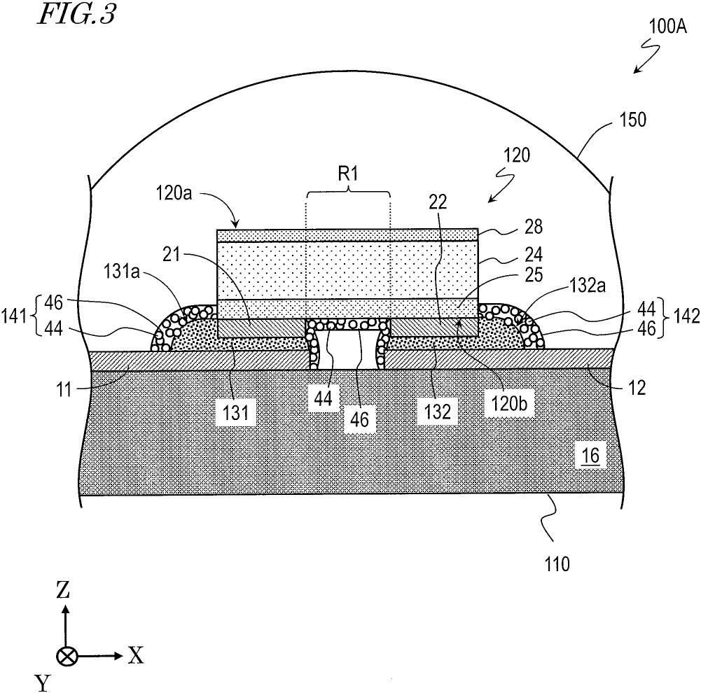

FIG. 3 schematically shows another example of the distribution of the light-reflective particles 44. In the example shown in FIG. 3, the light-reflective particles 44 and the flux 46 are also present on a region R1 (first region), which is a part of the lower surface 120b of the light-emitting element 120 exclusive of the electrodes 21, 22. Due to the presence of the light-reflective particles 44 on the region R1, light emitted from the lower surface 120b of the light-emitting element 120 can be reflected by the light-reflective particles 44 and, therefore, light absorbed by the substrate 110 can be reduced. That is, the light extraction efficiency can be further improved.

The flux 46 may not be substantially present on the region R1, but a light reflecting layer substantially composed of light-reflective particles 44 may be located on the region R1. The light-reflective particles 44 on the region R1 are covered with a part of the encapsulation member 150 which is present between the lower surface 120b of the light-emitting element 120 and the base 16, whereby the light-reflective particles 44 are retained on the region R1.

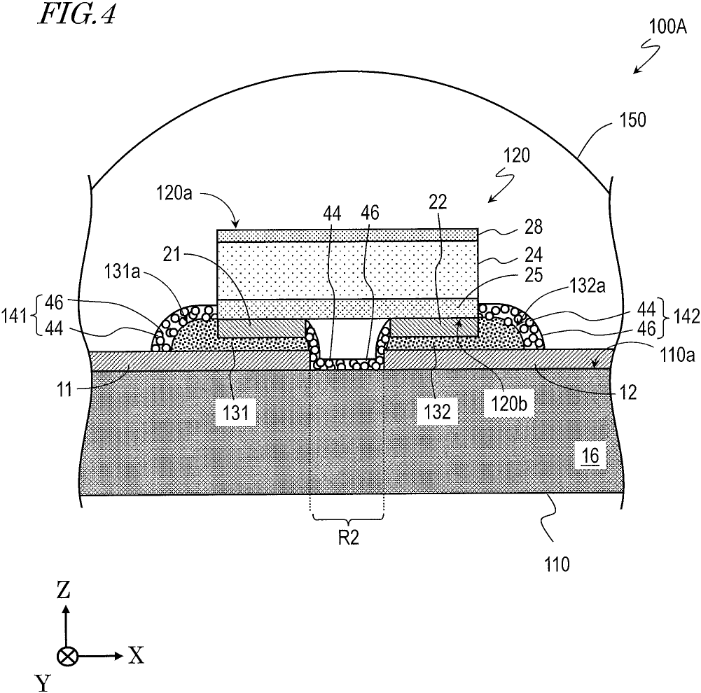

FIG. 4 schematically shows still another example of the distribution of the light-reflective particles. In the example shown in FIG. 4, the light-reflective particles 44 and the flux 46 are provided on the upper surface 110a of the substrate 110, i.e., one of the principal surfaces of the substrate 110 which is on the light-emitting element 120 side. In this example, the light-reflective particles 44 are present on a region R2 (second region), which is a part of the upper surface 110a of the substrate 110 exclusive of the wiring layer 10, rather than on the entire upper surface 110a of the substrate 110.

Due to the presence of the light-reflective particles 44 on the region R2 of the upper surface 110a of the substrate 110, reflection by the light-reflective particles 44 on the region R2 can be utilized to increase light traveling upward from the light-emitting unit 100A while absorption of light by the upper surface 110a of the substrate 110 is reduced. That is, the effect of improving the light extraction efficiency can be expected.

The flux 46 may not be substantially present on the region R2 as previously described for the region R1, but a light reflecting layer substantially composed of light-reflective particles 44 may be located on the region R2. The light-reflective particles 44 on the region R2 can also be covered with the encapsulation member 150 as well as the light-reflective particles 44 on the region R1 are. In other words, the encapsulation member 150 can cover both or one of the region R2 and the region R1.

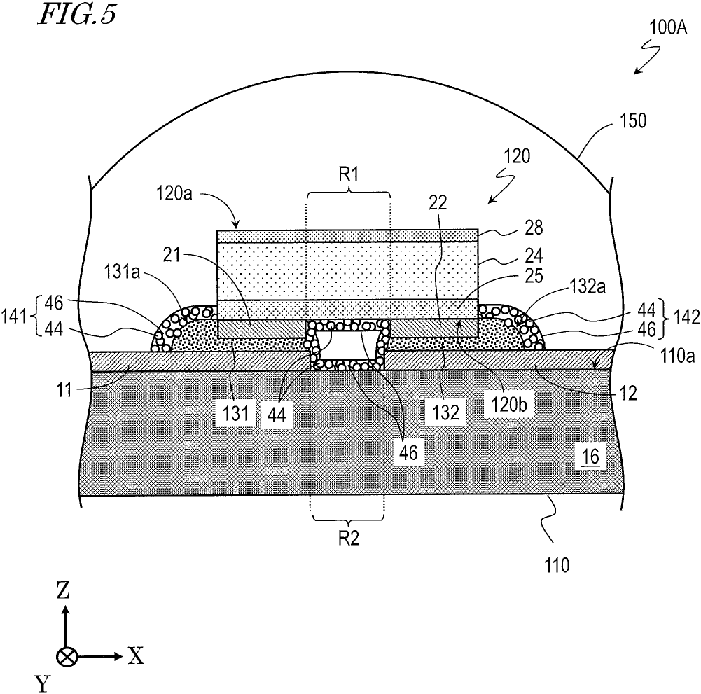

FIG. 5 schematically shows still another example of the distribution of the light-reflective particles. In the configuration illustrated in FIG. 5, the light-reflective particles 44 are present on both the region R1 of the lower surface 120b of the light-emitting element 120 and the region R2 of the upper surface 110a of the substrate 110. Note that the light-reflective particles 44 on the region R1 are located closer to the light-emitting element 120 than the light-reflective particles 44 on the region R2. Provision of the light-reflective particles 44 on the region R1 enables changing the traveling direction of light before the light widely diverges. From the viewpoint of reducing absorption of light by the substrate 110, providing the light-reflective particles 44 on the region R1 is more effective.

Furthermore, in the example shown in FIG. 5, a part of the encapsulation member 150 is present in the space between the region R1 and the region R2 in the Z direction. Since the encapsulation member 150 includes a portion that is present between the region R1 and the region R2, the light-reflective particles 44 on the region R1 and the light-reflective particles 44 on the region R2 can be covered with the encapsulation member 150. Since the encapsulation member 150 is arranged so as to cover the region R1 and the region R2, a decrease in reflectance which is attributed to falling off of the light-reflective particles 44 from the region R1 and/or the region R2, and hence a decrease in light extraction efficiency, can be avoided.

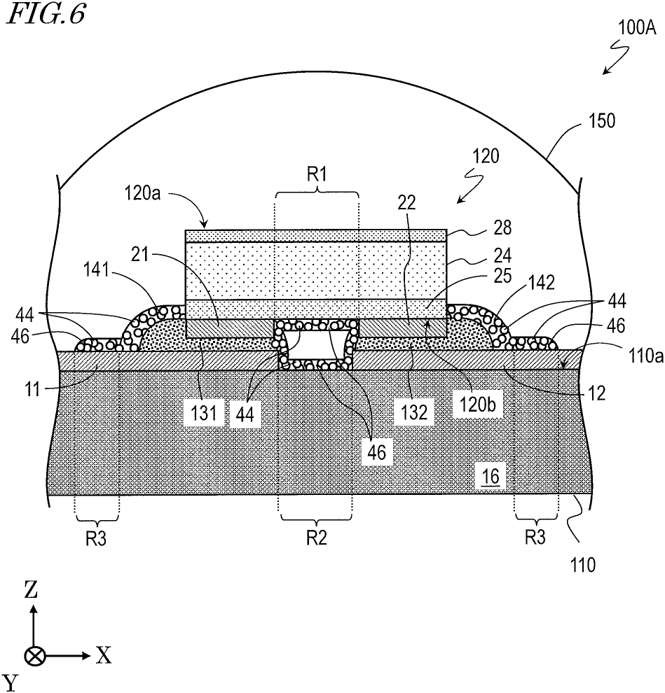

FIG. 6 schematically shows still another example of the distribution of the light-reflective particles. As shown in FIG. 6, some of the light-reflective particles 44 can be present on the wiring layer 10 of the substrate 110 (herein, on the first wiring 11 and on the second wiring 12). As illustrated in this example, the substrate 110 can include a region R3 in which light-reflective particles 44 are provided on the wiring layer 10. The region R3 can be a part of the wiring layer 10 which does not overlap the light-emitting element 120 in a plan view as viewed in the normal direction of the upper surface 110a of the substrate 110. In the plan view, the contour of the region R3 is typically indefinite. According to the configuration illustrated in FIG. 6, the light-reflective particles 44 are provided on a greater region on the upper surface 110a side of the substrate 110, so that a proportion of light emitted from the light-emitting element 120 which is absorbed by the wiring layer 10 can be reduced, and the extraction efficiency of the light can be further improved.

The flux 46 may not be substantially present on the region R3, but a light reflecting layer substantially composed of light-reflective particles 44 may be located on the region R3. The light-reflective particles 44 on the region R3 can also be covered with the encapsulation member 150 as well as the light-reflective particles 44 on the region R1 or the region R2 are.

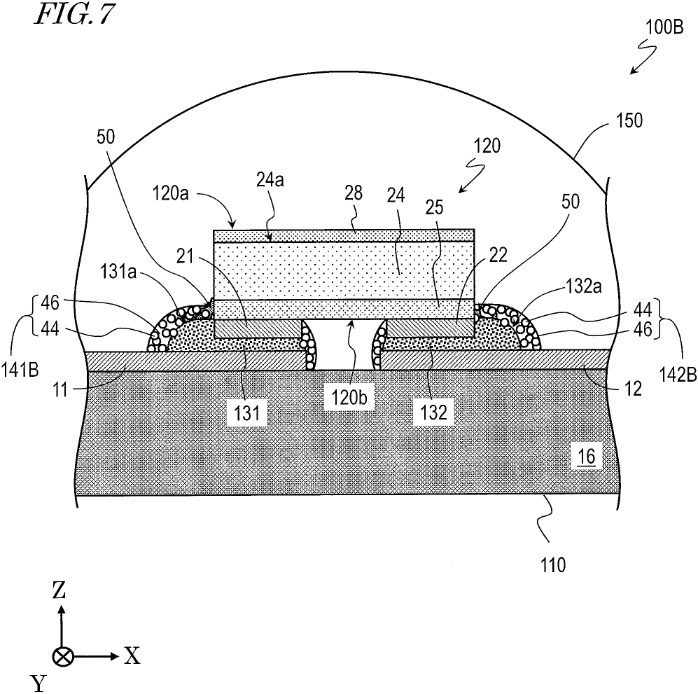

FIG. 7 schematically shows a cross section of a light-emitting unit according to another embodiment of the present disclosure. The light-emitting unit 100B shown in FIG. 7 is different from the light-emitting unit 100A shown in FIG. 2 in that the light-emitting unit 100B includes light reflecting layers 141B, 142B instead of the light reflecting layers 141, 142. One or both of the light reflecting layers 141B and 142B have one or more voids 50. The voids 50 are present near the light-emitting element 120 and typically in contact with the light-emitting element 120.

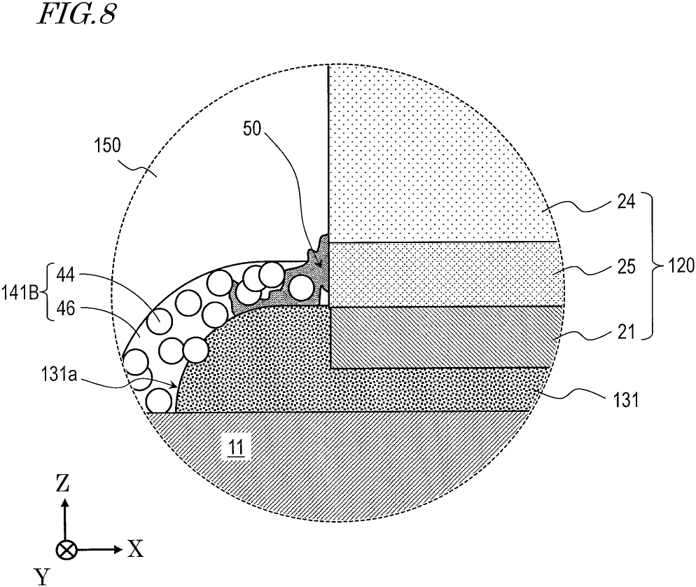

FIG. 8 is an enlarged view showing a part of FIG. 7. In the configuration illustrated in FIG. 8, the void 50 is in contact with the light-emitting element 120. As schematically shown in FIG. 8, a part of the void 50 can be present in the encapsulation member 150.

As will be described later, the void 50 is a space formed by photodecomposition of an organic substance in the flux contained in the solder composition used for formation of the light reflecting layers 141B, 142B. Therefore, as schematically shown in FIG. 8, the light-reflective particles 44 can be present inside the void 50. When the void is filled with air, the surfaces of the light-reflective particles 44 inside the void 50 form the interfaces with the air. Specifically, the difference in refractive index between the light-reflective particles 44 and a medium around the particles 44 is large as compared with the examples shown in FIG. 2, FIG. 3, FIG. 4, FIG. 5 and FIG. 6 where the light-reflective particles 44 are covered with the flux 46, and therefore, reflection at the surfaces of the light-reflective particles 44 can be utilized more effectively.

FIG. 9 shows an example of a cross section of a light-emitting unit according to still another embodiment of the present disclosure. The light-emitting unit 200 shown in FIG. 9 includes a substrate 210, which includes a base 26 and a wiring layer 20 on the base 26, and a plurality of light sources 220 mounted to the substrate 210. The light sources 220 can be two-dimensionally arrayed on the upper surface 210a side of the substrate 210. FIG. 9 shows two of the plurality of light sources 220, which are arranged along the X direction.

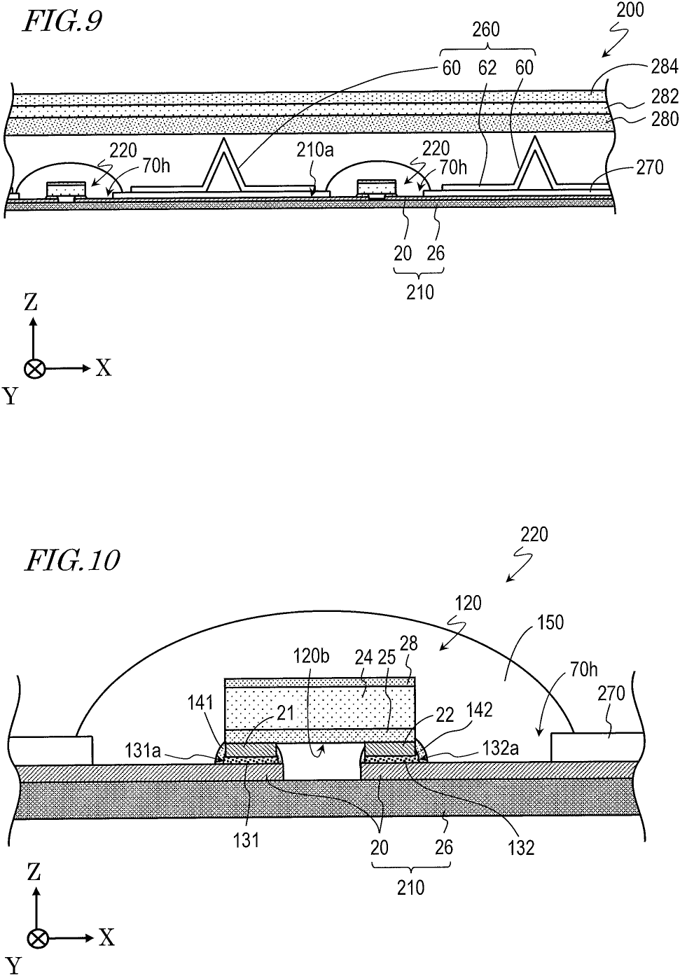

FIG. 10 is an enlarged view schematically showing one of the light sources 220 of the light-emitting unit 200 and its surroundings. Each of the plurality of light sources 220 has the same configuration as that of the light-emitting unit 100A or the light-emitting unit 100B, which has previously been described. In the configuration illustrated in FIG. 10, the light source 220 includes a light-emitting element 120 that has electrodes 21, 22 located on the lower surface 120b side, bonding members 131, 132 that couple the electrodes 21, 22 of the light-emitting element 120 with the wiring layer 20, and an encapsulation member 150 that covers the light-emitting element 120.

The light reflecting layer 141 is located on a part of the surface 131a of the bonding member 131 in the same fashion as in each of the above-described examples. Meanwhile, the light reflecting layer 142 is located on a part of the surface 132a of the bonding member 132. Since a part of the surface 131a of the bonding member 131 and a part of the surface 132a of the bonding member 132 are covered with the light reflecting layer 141 and the light reflecting layer 142, respectively, the extraction efficiency of the light can be improved due to diffuse reflection by the light-reflective particles 44. The configuration of each of the light-emitting elements 120 and its surroundings in the light-emitting unit 200 can be the same as that of any of the examples previously described with reference to FIG. 2, FIG. 3, FIG. 4, FIG. 5 and FIG. 6.

In the example shown in FIG. 9, the light-emitting unit 200 further includes a partition member 260 that includes a plurality of walls 60. In this example, an insulator layer 270, which has a plurality of through holes 70h, is provided between the partition member 260 and the wiring layer 20. As shown in FIG. 10, the encapsulation member 150, which covers the light-emitting element 120, may also cover a part of the wiring layer 20 exposed through the through hole 70h and a part of the insulator layer 270.

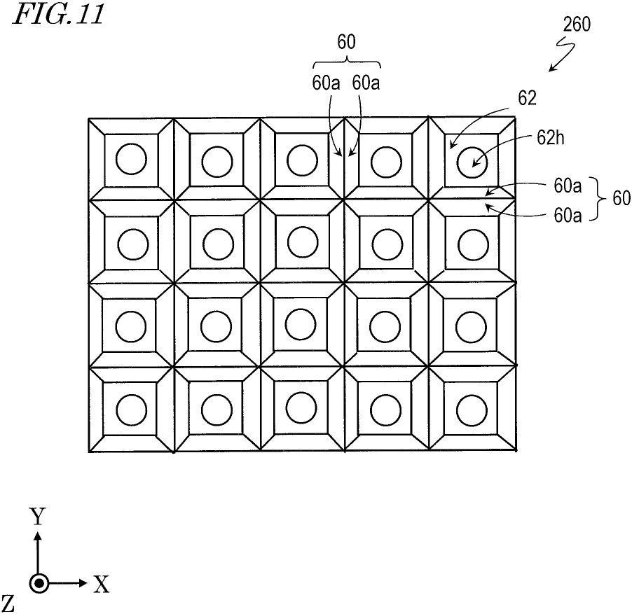

FIG. 11 schematically shows the partition member 260 taken out from the light-emitting unit 200. The walls 60 of the partition member 260 extend in the X direction or the Y direction, and each of the light sources 220 on the substrate 210 is surrounded by the walls 60.

The partition member 260 can further include a bottom 62, which is parallel to the upper surface 210a of the substrate 210. The bottom 62 has a plurality of through holes 62h, each of which has a circular opening, for example. Each of the light sources 220 is located inside a corresponding one of the through holes 62h. Since the partition member 260 has the bottom 62, part of the light emitted from the light sources 220 traveling toward the substrate 210 can be reflected by the bottom 62.

The partition member 260 is made of, for example, a resin material that contains a white filler. A part of the plurality of walls 60 which is present between two adjacent light sources 220 has slope surfaces 60a that are inclined with respect to the upper surface 210a of the substrate 210. Reflection at the slope surfaces 60a of the walls 60 is utilized so that the traveling direction of light from the light sources 220 can be oriented upward of the substrate 210. In this sense, the partition member 260 can also be referred to as a reflector.

As shown in FIG. 9, the light-emitting unit 200 can further include one or more optical sheets, including a wavelength conversion sheet, a prism sheet, a light diffuser sheet, etc., above the partition member 260. In the example shown in FIG. 9, the light-emitting unit 200 includes a wavelength conversion sheet 280 provided above the partition member 260, a prism sheet 282, and a light diffuser sheet 284 located above the prism sheet 282. In this example, the prism sheet 282 is provided between the wavelength conversion sheet 280 and the light diffuser sheet 284. The light-emitting unit 200 is applicable to, for example, the backlight unit of liquid crystal display devices.

### Exemplary Method for Producing Light-Emitting Unit

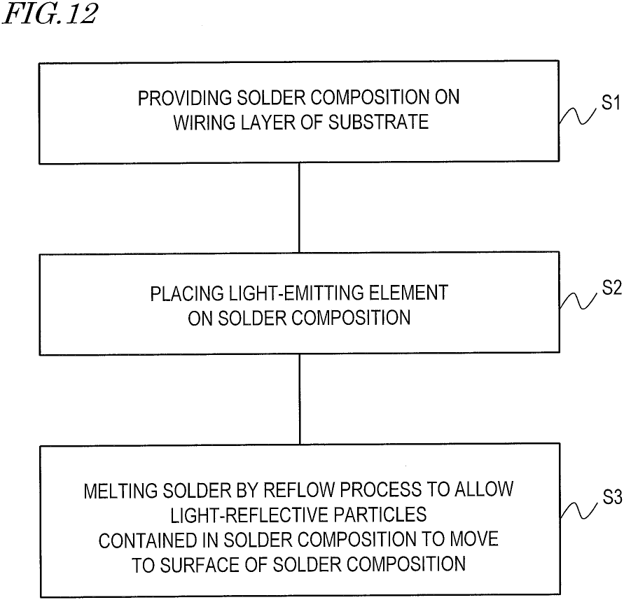

FIG. 12 shows an example of the method for producing a light-emitting unit according to still another embodiment of the present disclosure. The production method illustrated in FIG. 12 includes providing a solder composition on a wiring layer of a substrate (Step S1); placing a light-emitting element on the solder composition (Step S2); and melting a solder by a reflow process to allow the light-reflective particles contained in the solder composition to move to a surface of the solder composition (Step S3). Hereinafter, each of the steps is described in detail based on the example of the light-emitting unit 100A shown in FIGS. 1A and 1B.

### Step of Providing a Solder Composition on a Wiring Layer of a Substrate

Firstly, a substrate 110 that has a wiring layer 10 is provided and, as shown in FIG. 13, a solder composition 30 is provided at a predetermined position (e.g., on the land) of the wiring layer 10 (Step S1 of FIG. 12). In the example shown in FIG. 13, the solder composition 30 is placed on the surface of each of the first wiring 11 and the second wiring 12 of the wiring layer 10. A printing method can be applied to the provision of the solder composition 30.

In the present embodiment, as the solder composition 30, a mixture containing light-reflective particles 44 in addition to a solvent, a flux 46 and particles of solder 38 is placed at a predetermined position on the wiring layer 10.

The amount of the light-reflective particles 44 contained in the solder composition 30 is typically in the range of equal to or higher than 0.1 mass% and equal to or lower than 5 mass%, preferably in the range of equal to or higher than 0.7 mass% and equal to or lower than 2 mass%. When the solder composition 30 contains the light-reflective particles 44 in the proportion of 0.1 mass% or higher, the light reflecting layers 141, 142 formed after the reflow process can exhibit a relatively high reflectance for the light from the light-emitting element 120. By setting the proportion of the light-reflective particles 44 in the solder composition 30 to 5 mass% or lower, the solder composition 30 can be prevented from having an excessively high viscosity. Decrease in the viscosity of the solder composition 30 can facilitate application of the solder composition 30 by printing.

### Step of Placing a Light-Emitting Element on the Solder Composition

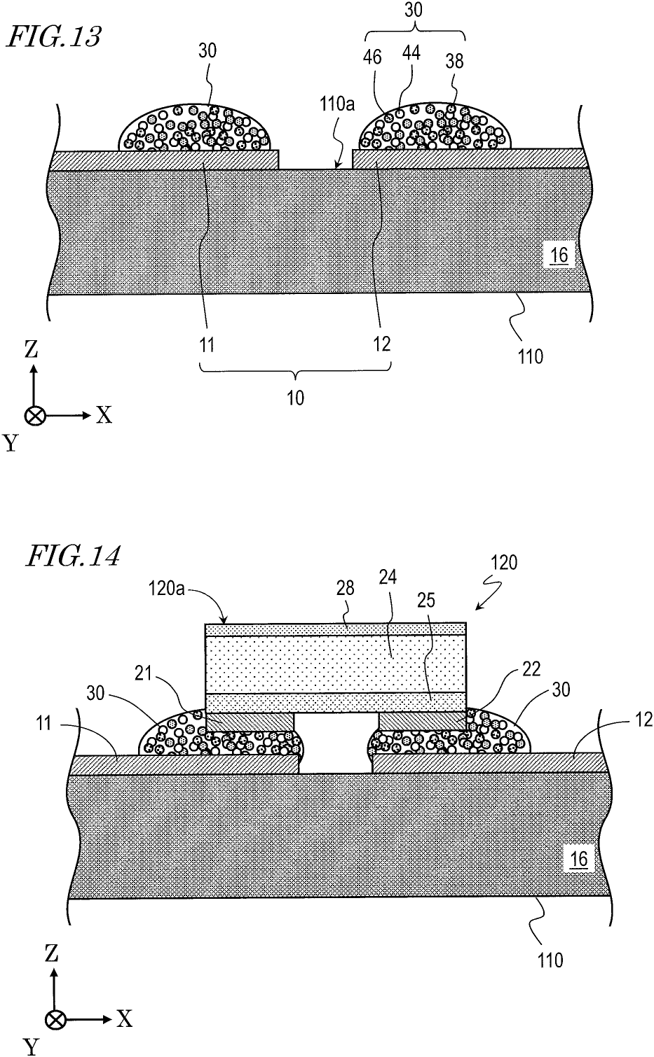

Next, a light-emitting element 120 is provided, and the light-emitting element 120 is placed on the solder composition 30 (Step S2 of FIG. 12). In this step, as shown in FIG. 14, the light-emitting element 120 is placed on the solder composition 30 such that the electrode 21 and the electrode 22 of the light-emitting element 120 face the solder composition 30 on the first wiring 11 and the solder composition 30 on the second wiring 12, respectively. Placing the light-emitting element 120 may involve pressing the light-emitting element 120 toward the substrate 110.

### Step of Moving the Light-Reflective Particles Contained In the Solder Composition to a Surface of the Solder Composition

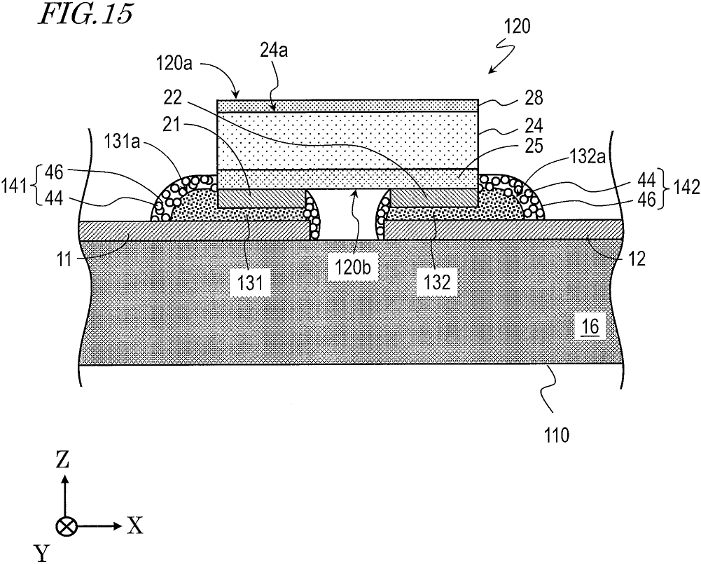

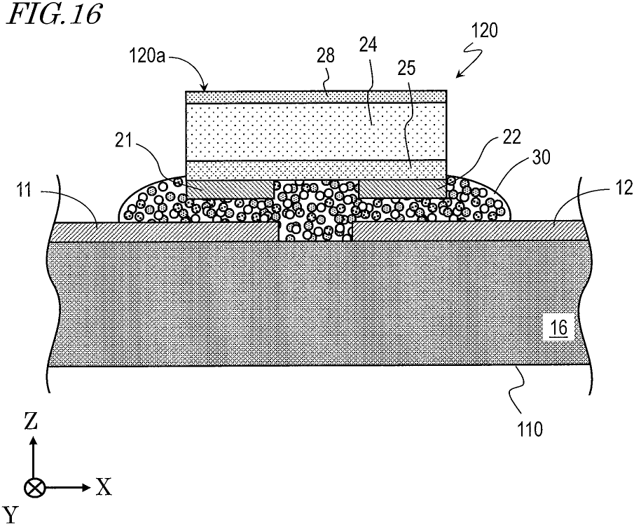

Next, the solder 38 in the solder composition 30 is melted by a reflow process such that the solder 38 electrically couples the electrodes 21, 22 with the wiring layer 10. When the solder 38 is solidified, the bonding member 131 having the light reflecting layer 141 located at a part of the surface 131a and the bonding member 132 having the light reflecting layer 142 located at a part of the surface 132a are formed as shown in FIG. 15 (Step S3 of FIG. 12).

Heating through the reflow process melts the solder 38, and particles of the solder 38 in the solder composition 30 start to bind together. Accordingly, due to the surface tension of the solder 38, the light-reflective particles 44 and the flux 46 are pushed to the external side of the solder 38. As a result, the light-reflective particles 44 move to the surface of the solder composition 30, so that the light reflecting layer 141 or the light reflecting layer 142 can be selectively formed on a part of the surface of each of the bonding member 131 and the bonding member 132 which is not in contact with any of the electrodes 21, 22 and the wiring layer 10. Note that some of the light-reflective particles 44 in the solder composition 30 can remain inside the solidified solder 38, i.e., inside the bonding member 131 or the bonding member 132.

After the reflow process is performed to form the light reflecting layers 141, 142, when necessary, an encapsulation member 150 can be formed so as to cover the light-emitting element 120. Typically, the encapsulation member 150 also covers the light reflecting layer 141 and the light reflecting layer 142. Covering the light reflecting layers 141, 142 with the encapsulation member 150 allows the light-reflective particles 44 to be prevented from falling off. The encapsulation member 150 can be formed of a light-transmitting resin material by potting, transfer molding, or the like. A part of the encapsulation member 150 can be located in a space between the lower surface 120b of the light-emitting element 120 and the upper surface 110a of the substrate 110.

The flux 46 pushed to the external side of the solder composition 30 by melting of the solder 38 in the step of the reflow process can be gradually decomposed through irradiation with light from the light-emitting element 120 (e.g., blue light). Since the light-emitting unit 100A includes the encapsulation member 150, the light-reflective particles 44 can be retained on the surface 131a of the bonding member 131 and the surface 132a of the bonding member 132, or on the surface 131a of the bonding member 131 or the surface 132a of the bonding member 132, even if the flux 46 is subjected to photodecomposition.

After the light reflecting layer 141 and the light reflecting layer 142 have been formed, the flux 46 can be at least partially removed by, for example, photodecomposition. The molecular weight of the material used as the flux 46 is, for example, equal to or smaller than 500. When the molecular weight of the material of the flux 46 is equal to or smaller than 500, the flux 46 is likely to be decomposed by irradiation with light from the light-emitting element 120 (e.g., blue light), and it is advantageous for posterior removal of the flux 46. If the molecular weight of the material of the flux 46 is excessively large, the reflectance in the light reflecting layer can decrease due to discoloration over time of the residue after the photodecomposition. If the molecular weight of the material of the flux 46 is relatively small, the decrease in reflectance which is attributed to such a phenomenon can be avoided.

Removal of the flux 46 can be carried out by intentional light irradiation or can be realized by unintentional photodecomposition. For example, when irradiated with light emitted from the light-emitting element 120 while the light-emitting unit 100A is in operation, part of the flux 46 in the light reflecting layer 141 or the light reflecting layer 142 which is present near the light-emitting element 120 can be lost with the passage of time. In such a case, due to photodecomposition of the flux 46, void(s) 50 is posteriorly formed in the vicinity of the light-emitting element 120, and a light-emitting unit 100B having the void(s) 50 as shown in FIG. 7 can be obtained. The void(s) 50 can be formed not only in the operation of the light-emitting unit 100A but also in a test operation prior to shipment.

Since the flux 46 is decomposed by photodecomposition, the surfaces of the light-reflective particles 44 covered with the flux 46 come into contact with a medium of a lower refractive index than the flux 46 (typically, air). That is, interfaces are formed between the lower refractive index medium and the light-reflective particles 44 and, accordingly, the effect of reflecting light from the light-emitting element 120 improves. Further, since the light-reflective particles 44 are also present inside the void(s) 50, the light-reflective particles 44 can remain in a region of large luminous flux, such as the vicinity of the light-emitting element 120, for example, while falling off of the light-reflective particles 44 is prevented.

The decomposition of the flux 46 by irradiation with light from the light-emitting element 120 occurs after the light-emitting element 120 has been encapsulated with a light-transmitting resin material, which is different from removal of the flux by washing. Therefore, photodecomposition of the flux 46 with the use of light from the light-emitting element 120 enables the light-reflective particles 44 to be provided inside the voids 50. On the other hand, if the step of washing away the flux 46 is performed after the light reflecting layer 141 and the light reflecting layer 142 have been formed, a large part of the flux 46 supporting the light-reflective particles 44 is removed from the light reflecting layers 141, 142. If thereafter the encapsulation member 150 is formed, the material of the encapsulation member 150 comes into the gap between the light-reflective particles 44. Thus, it is usually difficult to form a structure like the void 50. Note that, in removing the flux 46 by photodecomposition, it is not essential that the flux 46 is entirely removed. For example, part of the flux 46 can remain inside the voids 50.

The photodecomposition of the flux 46 with the use of light from the light-emitting element 120 can be more likely to occur in a region of larger luminous flux. That is, at the surfaces of the light-reflective particles 44 located in a region of larger luminous flux, the interface with air for example is more likely to be formed. This means that, in a region of larger luminous flux, a light-reflecting structure is more likely to be formed spontaneously, and the extraction efficiency of the light can be efficiently improved.

### Variation Example of Production Method

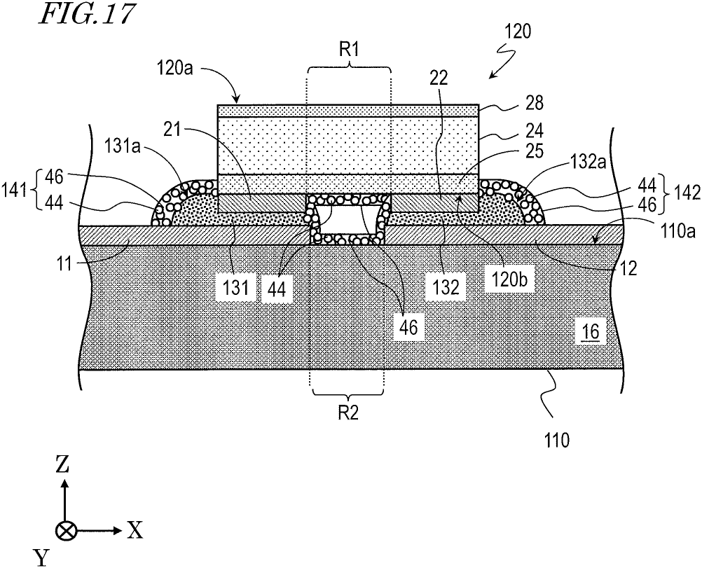

As previously described, in placing the light-emitting element 120 on the solder composition 30 after the solder composition 30 has been provided on the wiring layer 10, the light-emitting element 120 can be pressed toward the substrate 110. In this case, if the distance between the electrode 21 and the electrode 22 of the light-emitting element 120 is relatively short and accordingly the distance between the first wiring 11 and the second wiring 12 of the wiring layer 10 is short, the light-emitting element 120 can push the solder composition 30 so that a part of the solder composition 30 on the first wiring 11 and a part of the solder composition 30 on the second wiring 12 can come into contact with each other as schematically shown in FIG. 16.

Even if the solder composition 30 on the first wiring 11 and the solder composition 30 on the second wiring 12 are in contact with each other, they can be separated thereafter by performing a reflow process to melt the solder 38. That is, by performing the reflow process, a part of the solder composition 30 which is present between the first wiring 11 and the second wiring 12 is separated into a portion lying on the first wiring 11 and a portion lying on the second wiring 12 due to the difference in wettability between the base 16 and the wiring layer 10.

In this process, the solder 38 in the solder composition 30 moves to a region on the first wiring 11 or a region on the second wiring 12 and, as a result, the light-reflective particles 44 and the flux 46 in the solder composition 30 can remain in a region overlapping none of the first wiring 11 and the second wiring 12 as schematically shown in FIG. 17. FIG. 17 shows an example where the melted solder 38 moves away from a part of the upper surface 110a of the substrate 110 lying between the first wiring 11 and the second wiring 12, and some of the light-reflective particles 44 and part of the flux 46 in the solder composition 30 remain on the region R2 that is a part of the upper surface 110a exclusive of the wiring layer 10.

In the example shown in FIG. 17, other light-reflective particles 44 and another part of the flux 46 in the solder composition 30 are provided on the region R1, which is a part of the lower surface 120b of the light-emitting element 120 exclusive of the electrode 21 and the electrode 22 and which faces the substrate 110. Provision of the light-reflective particles 44 and the flux 46 on the region R1 can be realized by melting the solder 38 in the solder composition 30 and moving the solder 38 away from a part of the lower surface 120b of the light-emitting element 120 lying between the electrode 21 and the electrode 22. The light-reflective particles 44 and the flux 46 can be provided on both or one of the region R2 and the region R1.

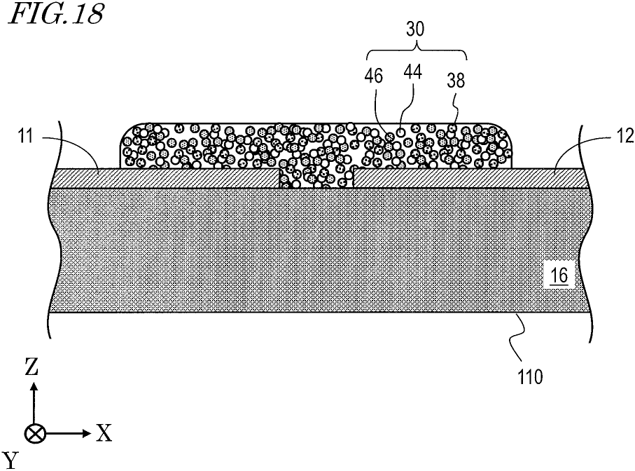

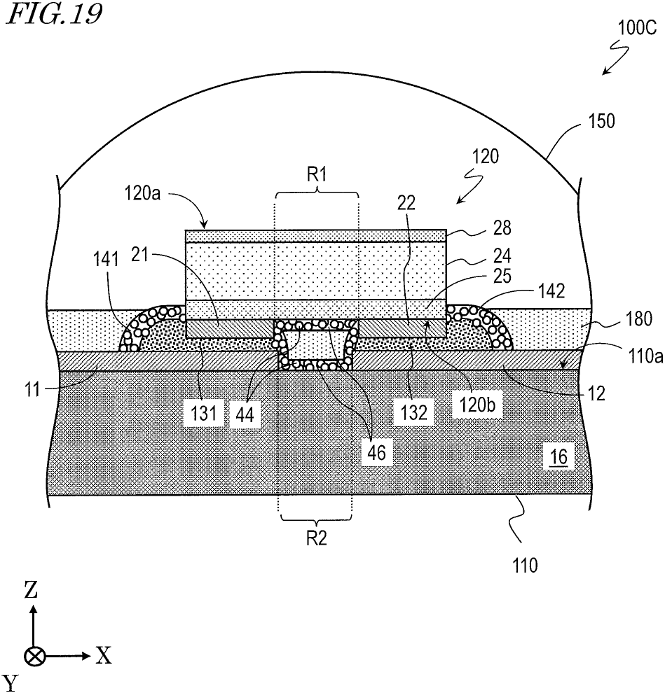

In providing the solder composition 30 on the wiring layer 10, the solder composition 30 can be placed on the wiring layer 10 so as to extend over the first wiring 11 and the second wiring 12 as schematically shown in FIG. 18. When the solder 38 in the solder composition 30 is melted by performing a reflow process, the melted solder 38 moves from a region between the first wiring 11 and the second wiring 12 in a cross section perpendicular to the upper surface 110a of the substrate 110 to a region on the first wiring 11 or the second wiring 12. That is, a part of the solder composition 30 that extends over the first wiring 11 and the second wiring 12 separates into a portion lying on the first wiring 11 and a portion lying on the second wiring 12. Therefore, also in this case, the light-reflective particles 44 and the flux 46 can remain in one or both of the region R2 and the region R1.

The space between the lower surface 120b of the light-emitting element 120 and the upper surface 110a of the substrate 110 may be filled with a light-transmitting encapsulation member or may be filled with a resin layer 180 as a so-called underfill, as in the light-emitting unit 100C shown in FIG. 19. The resin layer 180 is provided between the light reflecting layer on the substrate 110 and the light reflecting layer on the light-emitting element 120, each of which includes the light-reflective particles 44 and the flux 46, so that falling off of the light-reflective particles 44 can be prevented even if the flux 46 is lost by photodecomposition.

When the space between the light-emitting element 120 and the substrate 110 is filled with the resin layer 180 or the encapsulation member, occurrence of cracks in the bonding members 131, 132 due to the temperature cycle can be suppressed as compared with a case where the space is filled with a member that has a large coefficient of linear expansion and that is relatively hard, such as flux. The resin layer 180 can also cover the light reflecting layers 141, 142.

In placing the solder composition 30 on the wiring layer 10, if the amount of the solder composition 30 to be placed is large, part of the solder composition 30 can extend to the outside of a part of the wiring layer 10 overlapping the light-emitting element 120 in a plan view (for example, a portion outside the land of the first wiring 11 or a portion outside the land of the second wiring 12). Alternatively, after the solder composition 30 is placed on the wiring layer 10, when the light-emitting element 120 is pressed toward the substrate 110, the solder composition 30 can spread beyond the extent of the land of the wiring layer 10, for example. If the reflow process is performed with the thus-placed solder composition 30, mainly the solder 38 in the solder composition 30 gathers in a region between the electrodes 21, 22 of the light-emitting element 120 and the wiring layer 10 and, as a result, the light-reflective particles 44 and the flux 46 can remain on a part of the wiring layer 10 which does not overlap the light-emitting element 120 in a plan view (e.g., on the region R3 shown in FIG. 6). That is, as shown in FIG. 6, a light reflecting layer including these materials can be formed on a part of the wiring layer 10 which does not overlap the light-emitting element 120 in a plan view.

Hereinafter, components of a light-emitting unit according to an embodiment of the present disclosure are described in more detail.

### Light-Emitting Device 120

The light-emitting element 120 is a semiconductor device capable of emitting light according to a supplied electric current. A typical example of the light-emitting element 120 is an LED. As previously described, in the configuration illustrated in FIG. 2, the light-emitting element 120 includes a light-transmitting substrate 24 of, e.g., sapphire or gallium nitride, a semiconductor multilayer structure 25, a reflective film 28, and a pair of electrodes 21, 22.

The semiconductor multilayer structure 25 includes an n-type semiconductor layer, a p-type semiconductor layer, and an active layer interposed between the n-type semiconductor layer and the p-type semiconductor layer. The active layer may have a single quantum well (SQW) structure or a multiple quantum wells (MQW) structure that includes a plurality of well layers. The semiconductor multilayer structure 25 includes a plurality of semiconductor layers containing a nitride semiconductor. The nitride semiconductor includes all of the compositions represented by InₓAl_{y}Ga_{1-x-y}N ( 0≤x, 0≤y, x+y≤1) where x and y represent the proportions, each being variable within a predetermined range. The emission peak wavelength of the active layer can be appropriately selected according to the purpose. The active layer is configured to be capable of emitting visible light or UV light, for example.

The semiconductor multilayer structure 25 can include a plurality of light-emitting regions each including an n-type semiconductor layer, an active layer and a p-type semiconductor layer. When the semiconductor multilayer structure 25 includes a plurality of light-emitting regions, a plurality of well layers included in the semiconductor multilayer structure 25 can have different emission peak wavelengths or can have equal emission peak wavelengths. Note that having equal emission peak wavelengths includes a case where the emission peak wavelengths have variations of about several nanometers.

The combination of the emission peak wavelengths of the plurality of light-emitting regions can be appropriately selected. For example, when the semiconductor multilayer structure 25 includes two light-emitting regions, examples of the combination of light emitted from these light-emitting regions include blue light and blue light, green light and green light, red light and red light, ultraviolet light and ultraviolet light, blue light and green light, blue light and red light, and green light and red light. For example, when the semiconductor multilayer structure 25 includes three light-emitting regions, examples of the combination of light emitted from these light-emitting regions include combinations of blue light, green light and red light. Each of the light-emitting regions can include one or more well layers whose emission peak wavelengths are different from the other well layers.

The reflective film 28 is provided on the upper surface 24a of the light-transmitting substrate 24. Since the entire upper surface 24a of the light-transmitting substrate 24 is covered with the reflective film 28, light from the semiconductor multilayer structure 25 can be mainly extracted from the side surfaces of the light-emitting element 120 while the luminance on the optical axis of the light-emitting element 120 is appropriately reduced. A typical example of the reflective film 28 is a multilayer dielectric film. The reflective film 28 can be a metal film or a white resin layer.

The light-emitting element 120 includes the electrodes 21 and 22 as a pair of the positive and negative electrodes at the lower surface 120b. The shortest distance from the periphery of the electrode 21 to the periphery of the electrode 22 is, for example, equal to or greater than 50 µm and equal to or smaller than 500 µm. Examples of the material of the electrodes 21, 22 include gold, silver, tin, platinum, rhodium, titanium, aluminum, tungsten, palladium, nickel, and alloys containing one or more of these elements.

### Solder Composition 30

As previously described, the solder composition 30 contains the solder 38, the light-reflective particles 44, the flux 46 and the solvent. As the solder 38 in the solder composition 30, particles of a material usually used as solder can be employed. Examples of the material of the solder 38 include Au-containing alloys, Ag-containing alloys, Pdcontaining alloys, In-containing alloys, Pb-Pd containing alloys, Au-Ga containing alloys, Au-Sn containing alloys, Sncontaining alloys, Sn-Cu containing alloys, Sn-Cu-Ag containing alloys, Au-Ge containing alloys, Au-Si containing alloys, Al-containing alloys, and Cu-In containing alloys.

As the light-reflective particles 44, titanium oxide particles, aluminum oxide particles, silicon dioxide particles, or zirconium dioxide particles can be employed. The flux 46 is a mixture of a rosin and a solvent and can further contain an additive such as active agent. As the rosin of the flux 46, any of tall rosin, gum rosin, and wood rosin can be employed. The flux 46 may contain one or more types of acid modified rosins, which are produced by treating a rosin with an acid. When the flux 46 contains the acid modified rosin, improvement in wettability can be expected. Examples of the acid modified rosin include acrylic acid modified rosins, acrylic acid modified hydrogenated rosins, maleic acid modified rosins, and maleic acid modified hydrogenated rosins.

As the active agent, organic acids, halogen based active agents (e.g., organohalogen compounds or amine hydrohalides), amines, and organophosphorous compounds (e.g., phosphonate ester or phenyl substituted phosphinic acids) can be used. The flux 46 can contain only one type of the aforementioned compounds or can contain two or more types of the aforementioned compounds. The amount of each constituent of the solder composition 30 can be measured by, for example, ICP emission spectrometry according to the method stipulated in JIS Z 3910:2017.

Some commercially-available solder compositions contain a thermosetting resin, such as epoxy resin, for the purpose of improving the bonding strength. In contrast, the solder composition 30 does not contain an epoxy resin. The epoxy resin may be discolored by blue light. Since the solder composition 30 does not contain an epoxy resin, according to an embodiment of the present disclosure, the bonding members 131, 132 (or the light reflecting layers 141, 142) that are formed from the solder composition 30 can avoid decrease of the optical output which is attributed to discoloration of the epoxy resin. That is, according to an embodiment of the present disclosure, the reliability of the light-emitting unit can be secured over a long use period.

### Encapsulation Member 150

The encapsulation member (e.g., the encapsulation member 150) is made of an epoxy resin, silicone resin or fluoric resin, a mixture thereof, glass, or the like. Typically, the encapsulation member includes a dome portion that covers the light-emitting element 120. The material of the encapsulation member can contain an additional material having a different refractive index from that of the base material such that the additional material is dispersed in the material of the encapsulation member, so that the encapsulation member can have a light diffusing function. For example, the encapsulation member can include a light diffusing material, such as particles of silicon oxide, aluminum oxide, zirconium oxide or zinc oxide. As the light diffusing material dispersed in the base material, nanoparticles whose diameter defined by D₅₀ is equal to or greater than 1 nm and equal to or smaller than 100 nm may be used.

The encapsulation member can include a wavelength conversion material, such as phosphor, instead of or together with the light diffusing material. As the phosphor included in the encapsulation member, a known material can be employed. Examples of the phosphor include yttrium aluminum garnet based phosphors (e.g., Y₃(Al,Ga)₅O₁₂:Ce), lutetium aluminum garnet based phosphors (e.g., Lu₃(Al,Ga)₅O₁₂:Ce), terbium aluminum garnet based phosphors (e. g., Tb₃ (Al, Ga) ₅O₁₂: Ce), β sialon based phosphors (e.g., (Si,Al)₃(O,N)₄:Eu), α sialon based phosphors (e.g., Ca(Si,Al) ₁₂(O,N) ₁₆:Eu) , nitride based phosphors, and fluoride based phosphors. Examples of the nitride based phosphors include CASN based phosphors (e.g., CaAlSiN₃:Eu) and SCASN based phosphors (e.g., (Sr,Ca)AlSiN₃:Eu). Examples of the fluoride based phosphors include KSF based phosphors (e.g., K₂SiF₆:Mn), KSAF based phosphors (e.g., K₂(Si,Al)F₆:Mn) and MGF based phosphors (e.g., 3.5MgO·0.5MgF2·GeO₂:Mn) .

The yttrium aluminum garnet based phosphors (YAG based phosphors) are examples of a wavelength conversion material capable of converting blue light to yellow light. The β sialon based phosphors are examples of a wavelength conversion material capable of converting blue light to green light. The CASN based phosphors and the SCASN based phosphors are examples of a wavelength conversion material capable of converting blue light to red light. The KSF based phosphors, the KSAF based phosphors and the MGF based phosphors are also examples of a wavelength conversion material capable of converting blue light to red light. The phosphor can be a phosphor having a perovskite structure (e.g., CsPb(F,Cl,Br,I)₃) or a quantum dot phosphor (e.g., CdSe, InP, AgInS₂ or AgInSe₂) .

### Substrate 110, 210

The substrate 110 includes a base 16 and a wiring layer 10 supported by the base 16. The base 16 is an insulative member, which is made of a resin, glass, ceramic material, or the like. As the material of the base 16, a composite material, such as fiberglass-reinforced plastic (e.g., glass epoxy resin), can be used. As does the substrate 110, the substrate 210 shown in FIG. 9 also includes a base 26 and a wiring layer 20 supported by the base 26. The wiring layer 10 and the wiring layer 20 are electrically-conductive layers, which are made of a metal such as Cu, Fe, Ni, Al, Ag or Au, or an alloy including one or more of these elements. The substrate 210 can be a flexible printed circuit (FPC) board.

### Partition Member 260

As previously described with reference to FIG. 11, the light-emitting unit 200 includes a partition member 260, which includes a plurality of walls 60 surrounding each of the light sources 220. An example of the material of the partition member 260 is a resin material containing particles of an oxide, such as titanium oxide, aluminum oxide, or the like.

The shape of the partition member 260 can be realized by various molding methods with a die or by stereolithography. For example, the partition member 260 can be produced by vacuum forming from a sheet of polyethylene terephthalate (PET) containing white filler, such as oxide particles. The partition member 260 may be produced by providing a reflective material over a surface of a member produced by molding of a resin sheet that does not contain a white filler. The thickness of the resin sheet used for formation of the partition member 260 is, for example, 100 to 500 µm.

### Insulator Layer 270

The insulator layer 270 is made of a resin material, such as epoxy resin, urethane resin, acrylic resin, polycarbonate resin, polyimide resin, oxetane resin, silicone resin, modified silicone resin, or the like, and functions as an insulative resist. The insulator layer 270 can include particles of a light reflective material, such as titanium oxide, aluminum oxide, or the like, as does the partition member 260, so that the insulator layer 270 can further have the function of reflecting incoming light. Since the insulator layer 270 includes the light reflective particles, the utilization efficiency of light can be improved. When the employed partition member 260 has the bottom 62 as shown in FIG. 9, the insulator layer 270 is provided between the bottom 62 of the partition member 260 and the substrate 210.

### Wavelength Conversion Sheet 280, Prism Sheet 282 and Light Diffuser Sheet 284

In the configuration illustrated in FIG. 9, the light-emitting unit (the light-emitting unit 200) includes a wavelength conversion sheet 280, a prism sheet 282 and a light diffuser sheet 284. Typically, the wavelength conversion sheet 280, the prism sheet 282 and the light diffuser sheet 284 are provided in this order from the side closer to the substrate 210.

The wavelength conversion sheet 280 is typically made of a material containing a resin and particles of a phosphor or the like, which are dispersed in the resin. An example of the base material of the wavelength conversion sheet 280 is a material containing a silicone resin, modified silicone resin, epoxy resin, modified epoxy resin, urea resin, phenolic resin, acrylic resin, urethane resin or fluorine resin, or two or more types of these resins. As the phosphor contained in the wavelength conversion sheet 280, the aforementioned examples of the wavelength conversion material that can be dispersed in the encapsulation member can be employed. The thickness of the wavelength conversion sheet 280 can be in the range of, for example, equal to or greater than 100 µm and equal to or smaller than 200 µm.

The light diffuser sheet 284 is capable of diffusing and transmitting incoming light. The light diffusing structure can be formed in the light diffuser sheet 284 by providing recessed or raised portions in the surface of the light diffuser sheet 284 or dispersing a material of a different refractive index throughout the light diffuser sheet 284. The light diffuser sheet 284 is made of a material of low light absorption for visible light, such as polycarbonate resin, polystyrene resin, acrylic resin, polyethylene resin, or the like. As the light diffuser sheet 284, an optical sheet commercially available under names such as diffuser film can be used. The lower surface of the light diffuser sheet 284 can be separated from, or in contact with, the partition member 260.

The prism sheet 282 is configured to have an array of a plurality of prisms each extending in a predetermined direction. The prism sheet 282 has the function of refracting light incoming from various directions such that the traveling direction of the light changes to the +Z direction. For example, an Advanced Structured Optical Composite (ASOC) manufactured by 3 M can be used as the prism sheet 282.

A light-emitting unit produced according to an embodiment of the present disclosure is useful in various types of light sources for lighting, light sources for on-vehicle devices, light sources for display devices, etc. Particularly, embodiments of the present disclosure are advantageously applicable to backlight units for liquid crystal display devices.

It is to be understood that although certain embodiments of the present invention have been described, various other embodiments and variants may occur to those skilled in the art that are within the scope and spirit of the invention, and such other embodiments and variants are intended to be covered by the following claims.

What is claimed is:

1. A method for producing a light-emitting unit, the method comprising:
(A) providing a solder composition on a wiring layer of a substrate, the solder composition containing a solder, a flux, and light-reflective particles;
(B) placing a light-emitting element having at least one electrode on the solder composition such that the at least one electrode of the light-emitting element faces the solder composition; and
(C) melting the solder by a reflow process to allow the light-reflective particles to move to a surface of the solder composition, and to electrically couple the at least one electrode with the wiring layer via the solder.

2. The method of claim 1, wherein
the wiring layer of the substrate includes a first wiring and a second wiring,
(A) includes providing the solder composition on each of the first wiring and the second wiring,
(B) includes pressing the light-emitting element toward the substrate to allow a part of the solder composition on the first wiring and a part of the solder composition on the second wiring to come into contact with each other, and
(C) includes (C1) separating the solder composition into a portion lying on the first wiring and a portion lying on the second wiring.

3. The method of claim 2, wherein
the at least one electrode includes a first electrode and a second electrode,
the first electrode facing the first wiring and the second electrode facing the second wiring, and
(C1) includes providing some of the light-reflective particles and a part of the flux on one or both of a first region and a second region, the first region facing the substrate and being a part of a lower surface of the light-emitting element exclusive of the first electrode and the second electrode, and the second region being a part of an upper surface of the substrate on a light-emitting element side of the substrate exclusive of the first wiring and the second wiring.

4. The method of claim 1, wherein
the wiring layer of the substrate includes a first wiring and a second wiring,
(A) includes providing the solder composition on the wiring layer so as to extend over the first wiring and the second wiring, and
(C) includes (C1) separating a part of the solder included in the solder composition extending from the first wiring to the second wiring into a portion lying on the first wiring and a portion lying on the second wiring.

5. The method of claim 4, wherein
the at least one electrode includes a first electrode and a second electrode,
the first electrode facing the first wiring and the second electrode facing the second wiring, and
(C1) includes providing some of the light-reflective particles and a part of the flux on one or both of a first region and a second region, the first region facing the substrate and being a part of a lower surface of the light-emitting element exclusive of the first electrode and the second electrode, and the second region being a part of an upper surface of the substrate on a light-emitting element side of the substrate exclusive of the first wiring and the second wiring.

6. The method of claim 1, wherein the light-reflective particles are particles of titanium oxide, aluminum oxide, silicon dioxide or zirconium dioxide.

7. The method of claim 1, wherein, in (A), the solder composition contains the light-reflective particles in a proportion of equal to or higher than 0.1 mass% and equal to or lower than 5 mass%.

8. The method of claim 1, further comprising, after (C), (D) covering at least the light-reflective particles and the light-emitting element with an encapsulation member.

9. The method of claim 8, further comprising, after (D), (E) removing a part of the flux by photodecomposition.

10. The method of claim 2, further comprising, after (C), (D) covering at least the light-reflective particles and the light-emitting element with an encapsulation member.

11. The method of claim 4, further comprising, after (C), (D) covering at least the light-reflective particles and the light-emitting element with an encapsulation member.

12. A light-emitting unit comprising:
a light-emitting element having an upper surface and a lower surface that is opposite to the upper surface, the light-emitting element including a pair of electrodes provided at the lower surface;
a substrate having a wiring layer;
a bonding member located between the wiring layer of the substrate and each of the electrodes, the bonding member including a solder to electrically couple the electrodes with the wiring layer; and
a light reflecting layer located at a part of a surface of the bonding member that is in contact with neither the electrodes nor the wiring layer,
wherein the light reflecting layer includes light-reflective particles and a flux.

13. The light-emitting unit of claim 12, further comprising an encapsulation member located on the substrate, the encapsulation member covering at least the light reflecting layer and the light-emitting element.

14. The light-emitting unit of claim 13, wherein
the light reflecting layer has a void that is in contact with the light-emitting element, and
some of the light-reflective particles are present in the void.

15. The light-emitting unit of claim 12, wherein some of the light-reflective particles are provided on one or both of a first region and a second region, the first region being a part of the lower surface of the light-emitting element exclusive of the electrodes, and the second region being a part of an upper surface of the substrate on a light-emitting element side of the substrate exclusive of the wiring layer.

16. The light-emitting unit of claim 13, wherein
some of the light-reflective particles are provided on a first region and a second region, the first region being a part of the lower surface of the light-emitting element exclusive of the electrodes, and the second region being a part of an upper surface of the substrate on a light-emitting element side of the substrate exclusive of the wiring layer, and
the encapsulation member includes a portion located between the first region and the second region.

17. The light-emitting unit of claim 14, wherein
some of the light-reflective particles are provided on a first region and a second region, the first region being a part of the lower surface of the light-emitting element exclusive of the electrodes, and the second region being a part of an upper surface of the substrate on a light-emitting element side of the substrate exclusive of the wiring layer, and
the encapsulation member includes a portion located between the first region and the second region.

18. The light-emitting unit of claim 12, wherein the light reflecting layer covers 20% or more of the part of the surface of the bonding member that is in contact with neither the electrodes nor the wiring layer.

19. The light-emitting unit of claim 12, wherein the substrate includes a region in which the light-reflective particles are provided on the wiring layer.

20. The light-emitting unit of claim 12, wherein the light-reflective particles are particles of titanium oxide, aluminum oxide, silicon dioxide or zirconium dioxide.
